(19) United States
(12) Patent Application Publication
(10) Pub. No.: US 2025/0212353 A1
(43) Pub. Date: Jun. 26, 2025

(54) HOUSING OF ELECTRICAL APPARATUS

(71) Applicant: DENSO TEN Limited, Kobe (JP)

(72) Inventors: Hirofumi HAYASHI, Kobe (JP); Takumi Kyoto, Kobe (JP)

(73) Assignee: DENSO TEN Limited, Kobe (JP)

(21) Appl. No.: 18/985,892

(22) Filed: Dec. 18, 2024

(30) Foreign Application Priority Data
Dec. 21, 2023 (JP) 2023-215487

(51) Int. Cl. H05K 7/14

(52) U.S. Cl. CPC H05K 7/1427; H05K 7/1418

(57) ABSTRACT

A housing for storing a circuit board includes: an opening through which the circuit board is inserted; a closing wall facing to the front portion of the circuit board; a pair of side walls extending from the opening to the closing wall and facing each other, provided with a pair of second steps adapted to a pair of first steps at a boundary of the front portion and a rear portion of the circuit board; substrate guide surfaces, each provided on corresponding one of the side walls; a pair of first holders extending from the closing wall and provided along corresponding one of the side walls; and a pair of second holders extending from the pair of the second steps and provided along corresponding one of the side walls, the pair of second holders keeping a gap between the circuit board and the substrate guide surfaces.

### BACKGROUND OF THE INVENTION

### Field of the Invention

The invention relates to a housing of an electrical apparatus, and the electrical apparatus.

### Description of the Background Art

A housing of an electrical apparatus that accommodates and holds a substrate of the electrical apparatus, such as a printed board, in an internal space has been known. Such a housing includes guides that extend in an insertion direction of the substrate on a pair of side walls that face each other in the housing. Furthermore, a structure in which a closing wall that is opposite to an opening of the housing and a holder (regulator) that holds the substrate with respect to the pair of walls has been known (for example, the Japanese Published Unexamined Patent Application No.2021-40019).

In the above conventional technology, with the substrate held by the regulator, the substrate is in contact with a groove wall (guide surface) facing the substrate in a guide. There may be a slight gap between the substrate and the groove wall (guide surface) in terms of clearance. As a result, in the conventional technology, there has been a problem that the substrate and the groove wall (guide surface) intermittently come in contact with each other due to vibration caused by the gap, resulting in noise generation.

### SUMMARY OF THE INVENTION

According to one aspect of the invention, a housing of the electrical apparatus, for storing a circuit board, the circuit board having a front portion, a rear portion and a pair of first steps at a boundary therebetween such that the rear portion has a width wider than a width of the front portion, the housing including: an opening through which the circuit board is inserted; a closing wall facing to the front portion of the circuit board; a pair of side walls extending from the opening to the closing wall and facing each other, provided with a pair of second steps adapted to the pair of first steps; substrate guide surfaces, each provided on corresponding one of the side walls; a pair of first holders extending from the closing wall and provided along corresponding one of the side walls to hold a tip end of the front portion of the circuit board; and a pair of second holders extending from the pair of the second steps and provided along corresponding one of the side walls to hold the rear portion of the circuit board, the pair of second holders keeping a gap between the circuit board and the substrate guide surfaces.

It is an object of the invention to provide a housing of an electrical apparatus, the electrical apparatus, and a circuit board housing case capable of holding a substrate in a structure that suppresses occurrence of noise due to vibration.

These and other objects, features, aspects and advantages of the invention will become more apparent from the following detailed description of the invention when taken in conjunction with the accompanying drawings.

### BRIEF DESCRIPTION OF THE DRAWINGS

FIG. 1 is a horizontal cross-sectional plan view of an electrical apparatus according to an embodiment;

FIG. 2 is a partial front view of the electrical apparatus of FIG. 1;

FIG. 3 is a plan view of a substrate of the electrical apparatus of FIG. 1; FIG. 4 is a horizontal cross-sectional plan view of a housing of the electrical apparatus of FIG. 1;

FIG. 5 is a partial perspective view viewed from a front side of the housing of FIG. 3;

FIG. 6 is a vertical cross-sectional perspective view of a right end of the electrical apparatus of FIG. 2 along the line VI-VI;

FIG. 7 is a partial perspective view viewed from a back side of a lid of the electrical apparatus of FIG. 1; and

FIG. 8 is a vertical cross-sectional perspective view around the lid of the electrical apparatus of FIG. 2 along the line VI-VI.

### DESCRIPTION OF THE EMBODIMENTS

Hereinafter, an exemplary embodiment of this invention will be described in detail with reference to the accompanying drawings. For convenience of illustration, a three-dimensional orthogonal coordinate system is shown in these figures. With respect to the electrical apparatus 1, an X-axis direction is a “lateral left-right direction”, a Y-axis direction is a “front-rear direction”, and a Z-axis direction is an “upper-lower direction”. Specifically, a positive X-axis direction is a “right side”, a negative X-axis direction is a “left side”, a positive Y-axis direction is a “back (rear) side”, a negative Y-axis direction is a “front side”, a positive Z-axis direction is an “upper side”, and a negative Z-axis direction is a “lower side”. The terms “orthogonal” and “parallel” as used here are not limited to strictly orthogonal and parallel, but also include approximately orthogonal and approximately parallel.

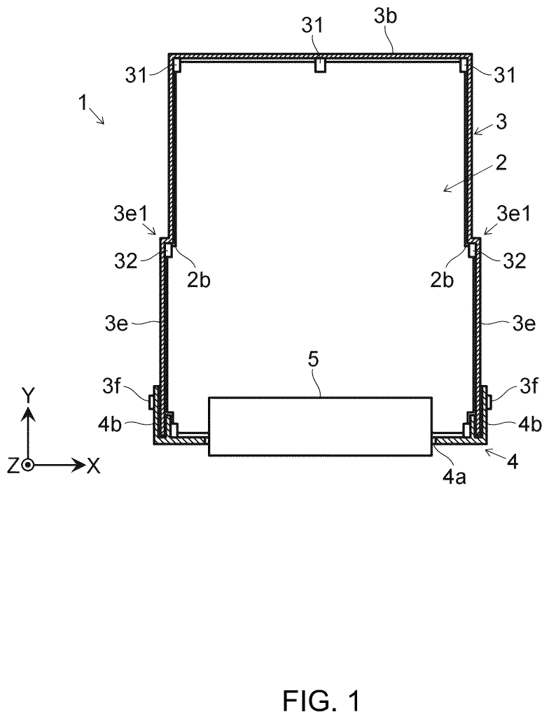

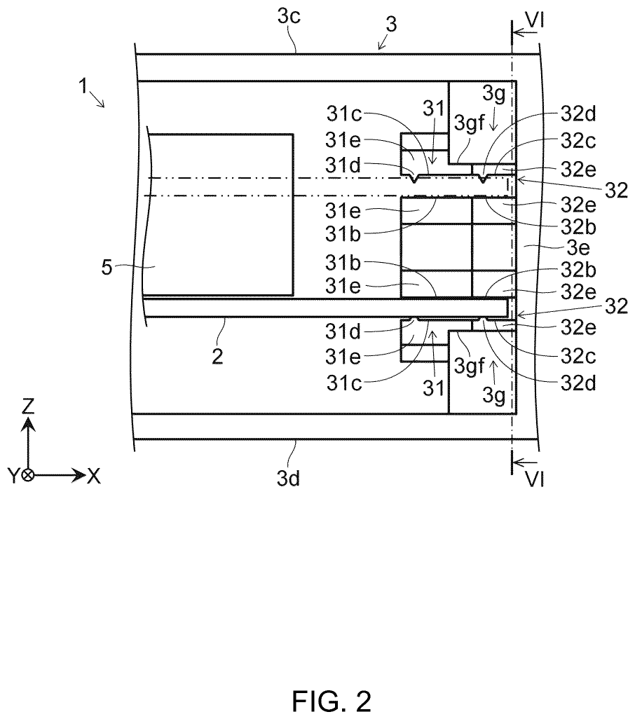

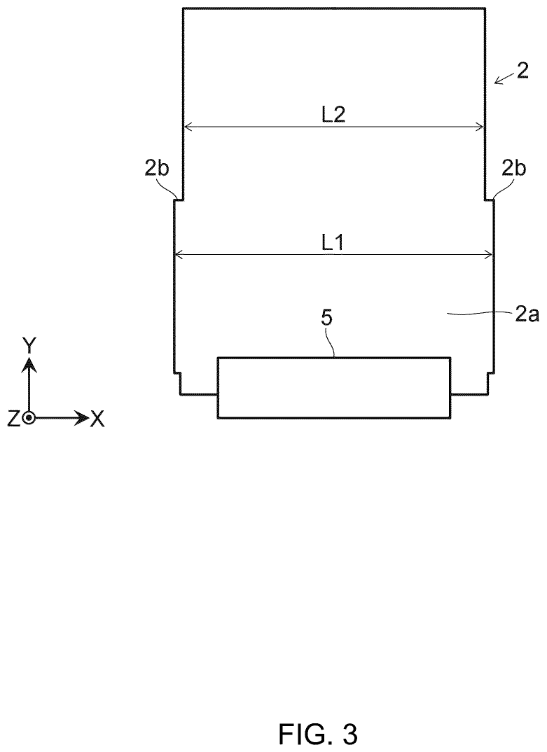

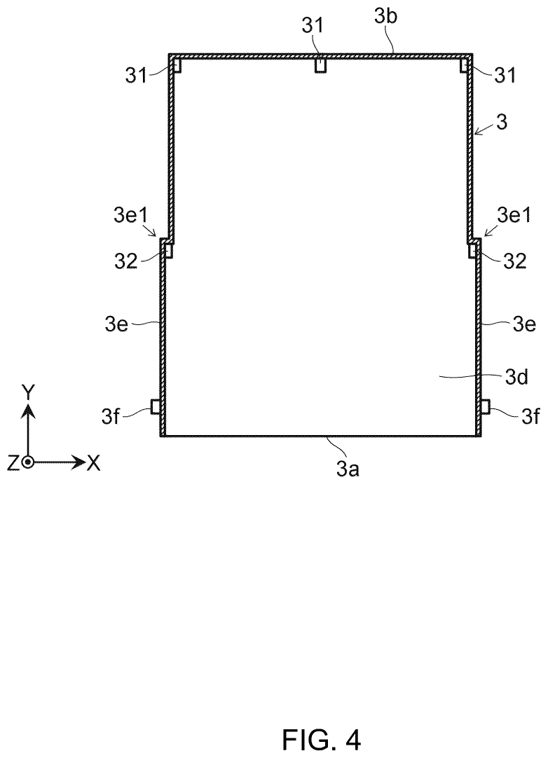

FIG. 1 is a horizontal cross-sectional plan view of an electrical apparatus 1 according to the embodiment. FIG. 2 is a partial front view of the electrical apparatus 1 of FIG. 1. FIG. 3 is a plan view of a substrate 2 of the electrical apparatus 1 of FIG. 1. FIG. 4 is a horizontal cross-sectional plan view of a housing 3 of the electrical apparatus 1 of FIG. 1. In FIG. 2, illustration of a lid 4 of the electrical apparatus 1 is omitted. FIG. 2 illustrates a part on the right side (positive X-axis direction side) of the electrical apparatus 1 viewed from the front side, but a part on the left side (negative X-axis direction side) of the electrical apparatus 1 has a similar structure.

The electrical apparatus 1 is, for example, a control device to be mounted in a vehicle, such as an automobile. The electrical apparatus 1 may be mounted in a mobile object other than the vehicle, and may be mounted in something other than the mobile object. The mobile object other the vehicle may be, for example, a vessel, an aircraft, or a robot. The electrical apparatus 1 is electrically connected to other devices via a connector 5 illustrated in FIG. 1 and FIG. 2.

The electrical apparatus 1 includes the substrate 2, the housing 3, and the lid 4.

The substrate 2 is, for example, a printed circuit board, and various parts are mounted on a principal surface 2a. The connector 5 is one of the parts to be mounted on the substrate 2. The connector 5 is fixed to a front side (negative Y-axis direction side) of the substrate 2. Harnesses, and the like, are electrically connected to the connector 5 from a front side of the electrical apparatus 1.

The substrate 2 is inserted into the housing 3 from a tip end on a back side (positive Y-axis direction side) and stored in the housing 3. That is, the substrate 2 is inserted into the housing 3 in parallel to a lower wall 3d of the housing 3 along the front-rear direction (Y-axis direction). In an assembled state of the electrical apparatus 1, the principal surface 2a of the substrate 2 extends in the lateral left-right direction and the front-rear direction (Y-axis direction). That is, the substrate 2 is fixed in the housing 3 in parallel to the lower wall 3d.

The substrate 2 is planar and has an approximately rectangular shape in a plan view. Specifically, the substrate 2 is provided with a step 2b in a center in the front-rear direction (Y-axis direction). The step 2b is located at left and right ends of the substrate 2. A width L1 in the lateral left-right direction (X-axis direction) closer to the front side (negative Y-axis direction side) than the step 2b of the substrate 2 is wider than a width L2 in the lateral left-right direction closer to the back side than the step 2b of the substrate 2. That is, the substrate 2 is provided with the steps 2b at left and right ends. A width between the steps 2b is wider on a side of an opening 3a (negative Y-axis direction side) than on a side of a closing wall 3b. In other words, the substrate 2 is a rectangular circuit board whose width at a rear end is wider than the width at the tip end in an insertion direction into the housing 3.

The housing 3 is a rectangular parallelepiped cylinder that extends in the front-rear direction (Y-axis direction) viewed from the front side (negative Y-axis direction side). The housing 3 is, for example, made from synthetic resin, but is not limited thereto. The housing 3 is a circuit board housing case in which the substrate 2 is stored. The housing 3 has the opening 3a, the closing wall (first side wall) 3b, an upper wall 3c, a lower wall 3d, and a pair of side walls (second side walls) 3e.

The opening 3a is located at an end on a front side (negative Y-axis direction side) of the housing 3. The opening 3a extends in the lateral left-right direction (X-axis direction) and the upper-lower direction (Z-axis direction). The closing wall 3b is located at an end on a back side (positive Y-axis direction side) of the housing 3, and is opposite to the opening 3a in the front-rear direction. The closing wall 3b is a flat plate that extends in the lateral left-right direction and the upper-lower direction. The closing wall 3b closes at the end on the back side of the housing 3 as a cylinder.

The housing 3 is formed into a rectangular parallelepiped cylinder by connecting the upper wall 3c, the lower wall 3d and the pair of side walls 3e that are respectively flat plates. The upper wall 3c, the lower wall 3d and the pair of side walls 3e are flat plates that extend from the opening 3a to the closing wall 3b in the front-rear direction (Y-axis direction). The pair of side walls 3e face each other in the lateral left-right direction and are disposed between the upper wall 3c and the lower wall 3d.

The lid 4 is disposed on the front side (negative Y-axis direction side) of the electrical apparatus 1. The lid 4 extends in the lateral left-right direction and the upper-lower direction, and removably closes the opening 3a of the housing 3. The lid 4 is, for example, made from synthetic resin, but is not limited thereto. The lid 4 has a window 4a and a pair of locking pieces 4b.

The window 4a is formed in a center of the lid 4 in a rectangular shape viewed from the front side, and penetrates the lid 4 in the front-rear direction (Y-axis direction). In the assembled state of the electrical apparatus 1, the connector 5 is exposed to outside through the window 4a of the lid 4. As a result, harnesses, and the like, are connected to the connector 5 from the front side of the electrical apparatus 1.

Each of the pair of locking pieces 4b is disposed at both ends in the lateral left-right direction (X-axis direction) of the lid 4. Each of the pair of locking pieces 4b is formed as a rectangular flat plate viewed from the lateral direction extending in the front-rear direction (Y-axis direction) and the upper-lower direction (Z-axis direction). In the assembled state of the electrical apparatus 1, each of the pair of locking pieces 4b is located outside each of the pair of side walls 3e of the housing 3. Each of the pair of locking pieces 4b has a hole 4c being placed in the center thereof and penetrating in the lateral left-right direction.

With respect to the pair of locking pieces 4b, each of a pair of protrusions 3f is formed on the pair of side walls 3e of the housing 3. Each of the pair of protrusions 3f is disposed at a front side end on an outside of each of the pair of side walls 3e and adjacent to the pair of locking pieces of the lid 4. In the assembled state of the electrical apparatus 1, each of the pair of protrusions 3f is inserted into the hole 4c of each of the pair of locking pieces 4b. The lid 4 is removably attached to the housing 3 in a snap-fit manner by elastically deforming the pair of locking pieces 4b to be connected/disconnected to/from the pair of protrusions 3f.

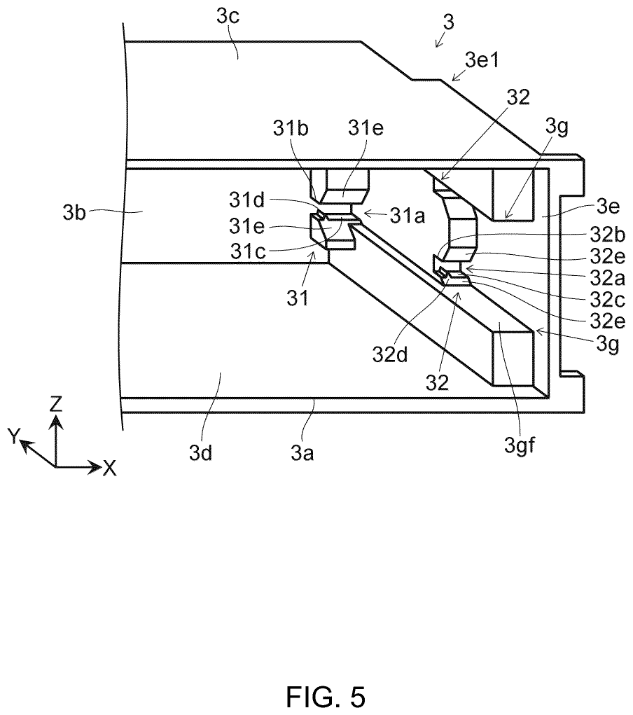

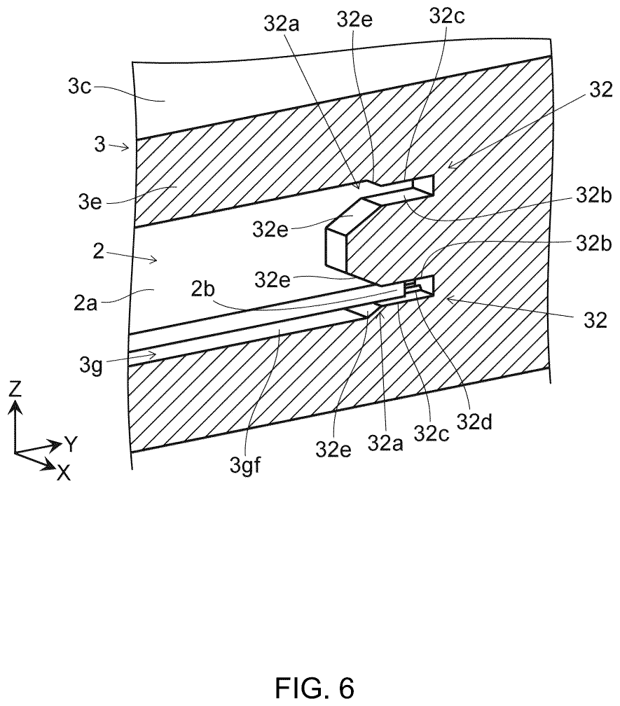

Subsequently, details of the housing 3 will be described. FIG. 5 is a partial perspective view viewed from the front side of the housing 3 of FIG. 3. FIG. 6 is a vertical cross-sectional perspective view of a right end of the electrical apparatus of FIG. 2 along the line VI-VI. Although each of FIG. 5 and FIG. 6 illustrates a periphery of a right one of the pair of side walls 3e (positive X-axis direction side) viewed from the front side of the housing 3, a periphery of a left one of the pair of side walls 3e (negative X-axis direction side) has a same structure.

The housing 3 has a pair of guides 3g, a first holder 31, and a second holder 32.

As illustrated in FIG. 2, in this embodiment, the housing 3 has a set of the pair of guides 3g, the first holders 31, and the second holders 32 at two places, on the upper side (positive Z-axis direction side) and lower side (negative Z-axis direction side) in the housing 3. Two sets of the pair of guides 3g, the first holders 31, and the second holders 32 on upper and lower sides are symmetrical in a vertical direction. In the following, the pair of guides 3g, the first holders 31, and the second holders 32 on the lower side in the housing 3 will be described.

Each of the pair of guides 3g is formed adjacent to an inside of each of the pair of left and right side walls 3e of the housing 3. Each of the pair of guides 3g extends along the front-rear direction (Y-axis direction) of the housing 3, i.e., an insertion direction of the substrate 2. Each of the pair of guides 3g has a guide surface (substrate guide surface) 3gf. The guide surface 3gf extends from an inner surface of each of the pair of side walls 3e to an interior of the housing 3 in a direction perpendicular to each of the pair of side walls 3e, i.e., the lateral left-right direction (X-axis direction). The guide surface 3gf faces the substrate 2 to be inserted into the housing 3, and guides a side end of the substrate 2 along the insertion direction (Y-axis direction).

Each of the first holders 31 is disposed adjacent to an inside of the closing wall 3b of the housing 3. Each of the first holders 31 is formed at two places adjacent to the inside of each of the pair of left and right side walls 3e and one place in a center in the lateral left-right direction (X-axis direction) (refer to FIGS. 1 and 4).

Each of the first holders 31 is formed as a recess recessed from the front side toward the back side in the front-rear direction (Y-axis direction). In other words, each of the first holders 31 extends to a side of the opening 3a of the housing 3. Each of the first holders 31 holds the tip end (positive Y-axis direction end) in the front-rear direction (Y-axis direction) of the substrate 2 by sandwiching the substrate 2 in the upper-lower direction (Z-axis direction). Each of the first holders 31 has an insertion opening 31a, an upper surface 31b, a lower surface 31c, and a rib 31d.

The insertion opening 31a is located at an end on a front side (negative Y-axis direction side) of each of the first holders 31. The insertion opening 31a extends in the lateral left-right direction (X-axis direction) and the upper-lower direction (Z-axis direction). The tip end of the substrate 2 to be inserted into the housing 3 passes through the insertion opening 31a and is inserted into the first holders 31.

The upper surface 31b and the lower surface 31c extend in the lateral left-right direction (X-axis direction) and the front-rear direction (Y-axis direction) on upper and lower sides of each of the first holders 31 as a recess. The upper surface 31b and the lower surface 31c face the substrate 2 in the upper-lower direction, and sandwich and hold the substrate 2 therebetween.

The rib 31d is formed on the lower surface 31c. The rib 31d protrudes to the upper side (positive Z-axis direction) from the lower surface 31c toward the upper surface 31b. A shape of the rib 31d viewed from the front side is, for example, a triangle having a vertex at an upper end.

A distance between the vertex of the rib 31d and the upper surface 31b before the substrate 2 is inserted into the first holders 31 is shorter than a thickness of the substrate 2. The rib 31d is a crush rib (squeezing rib). When the substrate 2 is inserted into the first holders 31, the tip end of the substrate 2 is pressed against the ribs 31d as crush ribs and crush the ribs 31d to be held by the first holders 31 by a reaction force of the ribs 31d.

Each of the second holders 32 is disposed adjacent to the inside of each of the pair of side walls 3e. Each of the second holders 32 corresponds to a location of the step 2b of the substrate 2 inserted into the housing 3 and is formed in the center in the front-rear direction (Y-axis direction) of each of the pair of side walls 3e. That is, each of the second holders 32 is disposed closer to the side of the opening 3a than each of the first holders 31. Each of the pair of side walls 3e is provided with a step 3e1 that is wider on the side of the opening 3a than on the side of the closing wall 3b, corresponding to the location of the step 2b of the substrate 2.

Each of the second holders 32 is formed as a recess recessed from the front side toward the back side in the front-rear direction (Y-axis direction). In other words, each of the second holders 32 extends to the side of the opening 3a of the housing 3. Each of the second holders 32 holds the step 2b at each of the side ends in the lateral left-right direction (X-axis direction) of the substrate 2 by sandwiching the substrate 2 in the upper-lower direction (Z-axis direction). Each of the second holders 32 has an insertion opening 32a, an upper surface 32b, a lower surface 32c, and a rib 32d.

The insertion opening 32a is located at an end on the front side (negative Y-axis direction side) of each of the second holders 32. The insertion opening 32a extends in the lateral left-right direction (X-axis direction) and the upper-lower direction (Z-axis direction). The side ends of the steps 2b of the substrate 2 to be inserted into the housing 3 pass through the insertion openings 32a and are inserted into the second holders 32.

The upper surface 32b and the lower surface 32c extend in the lateral left-right direction (X-axis direction) and the front-rear direction (Y-axis direction) on upper and lower sides of each of the second holders 32 as a recess. The upper surface 32b and the lower surface 32c face the substrate 2 in the upper-lower direction, and sandwich and hold the substrate 2 therebetween.

The rib 32d is formed on the lower surface 32c. The rib 32d protrudes to the upper side (positive Z-axis direction) from the lower surface 32c toward the upper surface 32b. A shape of the rib 32d viewed from the front side is, for example, a triangle having a vertex at an upper end.

A distance between the vertex of the rib 32d and the upper surface 31b before the substrate 2 is inserted into the second holders 32 is shorter than the thickness of the substrate 2. The rib 32d is a crush rib (squeezing rib). When the substrate 2 is inserted into the second holders 32, the side ends of the steps 2b of the substrate 2 are pressed against the ribs 32d as crush ribs and crush the ribs 32d to be held by the second holders 32 by a reaction force of the ribs 32d.

Each of the second holders 32 is disposed on the upper side (positive Z-axis direction side) than the guide surface 3gf of each of the pair of guides 3g. In other words, each of the second holders 32 is separated from the guide surface 3gf in a normal direction of the guide surface 3gf. Each of the second holders 32 holds each of the steps 2b of the substrate 2 while being separated from the guide surface 3gf in the normal direction of the guide surface 3gf.

According to the configuration described above, with the substrate 2 held in the housing 3, even when vibration occurs in the housing 3, the substrate 2 does not come into contact with the guide surface 3gf. Therefore, in the housing 3 of the electrical apparatus 1, the substrate 2 is capable of being held in a structure that suppresses occurrence of noise due to vibration.

Each of the first holders 31 is disposed on the upper side (positive Z-axis direction side) than the guide surface 3gf of each of the pair of guides 3g. In other words, each of the first holders 31 is separated from the guide surface 3gf in the normal direction of the guide surface 3gf. Each of the first holders 31 holds the tip end of the substrate 2 while being separated from the guide surface 3gf in the normal direction of the guide surface 3gf.

According to the configuration described above, also with respect to the first holders 31, with the substrate 2 held in the housing 3, even when vibration occurs in the housing 3, the substrate 2 does not come into contact with the guide surface 3gf. Therefore, in the housing 3 of the electrical apparatus 1, the substrate 2 is capable of being held in the structure that suppresses occurrence of noise due to vibration.

The insertion opening 31a of each of the first holders 31 and the insertion opening 32a of each of the second holders 32 face in a direction in which the opening 3a of the housing 3 is located. In other words, the insertion opening 31a and the insertion opening 32a face the side of the opening 3a in the insertion direction (front-rear direction (Y-axis direction)) of the substrate 2.

According to the configuration described above, with insertion of the substrate 2 into the housing 3, the tip end and the side ends of the substrate 2 respectively pass through the insertion openings 31a and the insertion openings 32a and are inserted into the first holders 31 and the second holders 32. Therefore, the substrate 2 that has been inserted into the housing 3 is capable of being easily held by the first holders 31 and the second holders 32.

Each of the first holders 31 has a slope 31e. The slope 31e is disposed on front upper and lower sides of each of the insertion openings 31a of the first holders 31. Similarly, each of the second holders 32 has a slope 32e. The slope 32e is disposed on front upper and lower sides of each of the insertion openings 32a of the second holders 32.

The slopes 31e and 32e on the upper side are inclined downward toward the insertion openings 31a, 32a as approaching from the opening 3 of the housing 3 to the insertion openings 31a, 32a along the insertion direction (front-rear direction (Y-axis direction)) of the substrate 2. The slopes 31e and 32e on the lower side are inclined upward toward the insertion openings 31a, 32a to be separated from the guide surface 3gf as approaching from the opening 3 of the housing 3 to the insertion openings 31a, 32a along the insertion direction (front-rear direction (Y-axis direction)) of the substrate 2.

According to the configuration described above, with insertion of the substrate 2 into the housing 3, the tip end of the substrate 2 voluntarily enters each of the first holders 31 along the slopes 31e and the side ends of the steps 2b of the substrate 2 voluntarily enter each of the second holders 32 along the slopes 32e. Thus, the substrate 2 is capable of being separated from the guide surface 3gf while the substrate 2 is held by the first holders 31 and the second holders 32. Therefore, the substrate 2 that has been inserted into the housing 3 is capable of being held while the substrate 2 is easily separated from the guide 3gf.

As described above, the housing 3 has a plurality sets (in this embodiment, two sets) of the pair of guides 3g, the first holders 31, and the second holders 32. The two sets of the pair of guides 3g, the first holders 31, and the second holders 32 are arranged on the upper-lower direction (Z-axis direction), in other words, arranged in the normal direction of the guide surface 3gf.

According to the configuration described above, by changing orientation of the principal surface 2a of the substrate 2, the substrate 2 is capable of being stored on the upper side in the housing 3. At this time, on both the upper side and the lower side of the housing 3, the side ends of the steps 2b of the substrate 2 are capable of being held by the second holders 32 while being separated from the guide surface 3gf. That is, even when the orientation of the substrate 2 is changed and stored on the upper side in the housing 3, it is possible to suppress occurrence of noise due to vibration and hold the substrate 2.

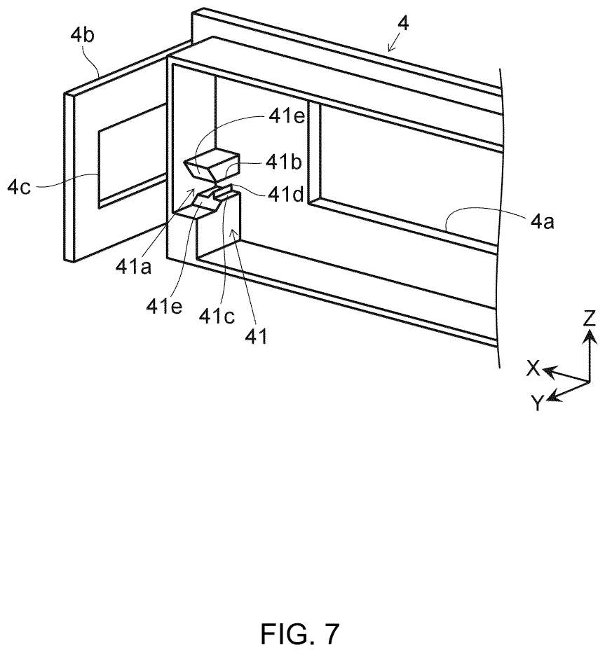

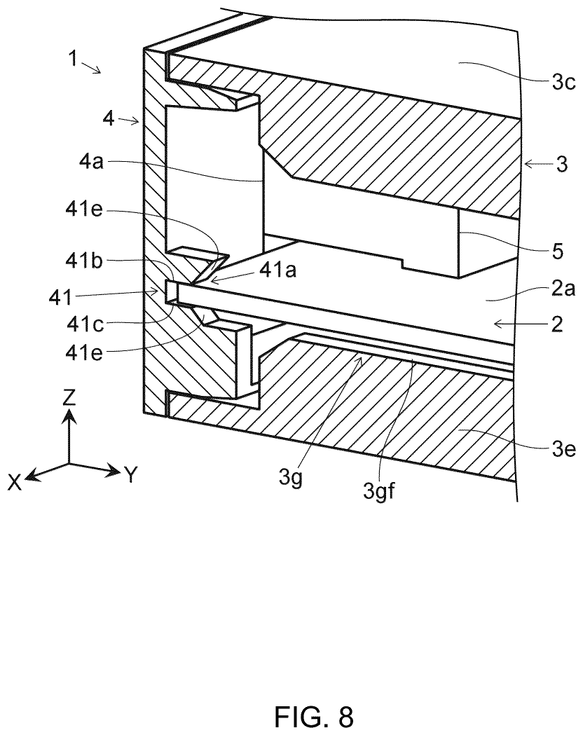

Subsequently, details of the lid 4 will be described. FIG. 7 is a partial perspective view viewed from a back side of the lid 4 of the electrical apparatus of FIG. 1. FIG. 8 is a vertical cross-sectional perspective view around the lid 4 of the electrical apparatus 1 of FIG. 2 along the line VI-VI. Although each of FIG. 7 and FIG. 8 illustrates a periphery of a right one of the pair of side walls 3e (positive X-axis direction side) viewed from the front side of the housing 3, a periphery of a left one of the pair of side walls 3e (negative X-axis direction side) has a same structure.

The lid 4 has a third holder 41. The third holder 41 is disposed adjacent to an inside of the lid 4 and each of the pair of side walls 3e of the housing 3 in the assembled state of the electrical apparatus 1. The third holder 41 is formed on a front side (negative Y-axis direction side) of each of the pair of guides 3g of the housing 3.

The third holder 41 is formed as a recess recessed from the back side toward the front side in the front-rear direction (Y-axis direction). The third holder 41 holds the rear end (negative Y-axis direction end) in the front-rear direction (Y-axis direction) of the substrate 2 by sandwiching the substrate 2 in the upper-lower direction (Z-axis direction). In other words, the third holder 41 holds an end on a side of the connector 5 in the front-rear direction of the substrate 2. The third holder 41 has an insertion opening 41a, an upper surface 41b, a lower surface 41c, a rib 41d, and a slope 41e.

The insertion opening 41a is located at an end on a back side (positive Y-axis direction side) of the third holder 41. The insertion opening 41a extends in the lateral left-right direction (X-axis direction) and the upper-lower direction (Z-axis direction). The insertion opening 41a faces in a direction in which the housing 3 is located in the front-rear direction (Y-axis direction). The rear end of the substrate 2 passes through the insertion openings 41a and is inserted into the third holder 41.

The upper surface 41b and the lower surface 41c extend in the lateral left-right direction (X-axis direction) and the front-rear direction (Y-axis direction) on upper and lower sides of the third holder 41 as a recess. The upper surface 41b and the lower surface 41c face the substrate 2 in the upper-lower direction, and sandwich and hold the substrate 2 therebetween.

The rib 41d is formed on the lower surface 41c. The rib 41d protrudes to the upper side (positive Z-axis direction) from the lower surface 41c toward the upper surface 41b. A shape of the rib 41d viewed from the back side is, for example, a triangle having a vertex at an upper end.

A distance between the vertex of the rib 41d and the upper surface 41b before the substrate 2 is inserted into the third holder 41 is shorter than the thickness of the substrate 2. The rib 41d is a crush rib (squeezing rib). When the substrate 2 is inserted into the third holder 41, the tip end of the substrate 2 is pressed against the ribs 41d as crush ribs and crush the ribs 41d to be held by the third holder 41 by a reaction force of the ribs 41d.

The second holder 41 is disposed on the upper side (positive Z-axis direction side) than the guide surface 3gf of each of the pair of guides 3g. In other words, the third holder 41 is separated from the guide surface 3gf in the normal direction of the guide surface 3gf. The third holder 41 holds the rear end of the substrate 2 while being separated from the guide surface 3gf in the normal direction of the guide surface 3gf.

The slope 41e is disposed on back upper and lower sides of each of the insertion openings 41a of the third holder 41. The slope 41e on the upper side is inclined downward toward each of the insertion openings 41a as approaching from the housing 3 to each of the insertion openings 41a along the insertion direction (front-rear direction (Y-axis direction)) of the substrate 2. The slopes 41e on the lower side are inclined upward toward each of the insertion openings 41a to be separated from the guide surface 3gf as approaching from the housing 3 to each of the insertion openings 41a along the insertion direction (front-rear direction (Y-axis direction)) of the substrate 2.

According to the configuration described above, also in the lid 4, the substrate 2 is capable of being held by the third holder 41 while being separated from the guide surface 3gf. The rear end of the substrate 2 voluntarily enters the third holder 41 along the slopes 41e. Thus, the substrate 2 is capable of being easily guided into the third holder 41.

The first holders 31, the second holders 32, and the third holder 41 are formed to have a same height in the upper-lower direction (Z-axis direction). Specifically, the lower surface 31c of each of the first holders 31, the lower surface 32c of each of the second holders 32, and the lower surface 41c of the third holder 41 are separated from the guide surface 3gf in the normal direction of the guide surface 3gf by a same distance. Thus, the substrate 2 is held parallel to the guide surface 3gf at a fixed distance in the housing 3. Therefore, in the housing 3 of the electrical apparatus 1, the substrate 2 is capable of being held in the structure that surely suppresses occurrence of noise due to vibration.

In this embodiment, the housing 3 has two sets of the pair of guides 3g, the first holders 31, the second holders 32 in the upper-lower direction (Z-axis direction). On the other hand, the lid 4 has a single third holder 41 in the upper-lower direction (Z-axis direction). The third holder 41 faces one of the two sets of the pair of guides 3g, the first holders 31, the second holders 32 (the lower one in this embodiment) in the insertion direction of the substrate 2.

When a holding position of the substrate 2 is on the upper side (positive Z-axis direction side) in the housing 3, the lid 4 is turned upside down and attached to the housing 3 so that the third holder 41 is located on the upper side. In other words, the lid 4 is attached to the housing 3 by switching orientation of the lid 4 in the normal direction of the guide surface 3gf (upper-lower direction (Z-axis direction)). Thus, the third holder 41 does not needed to be provided at two places, i.e., on the upper side (positive Z-axis direction side) and the lower side (negative Z-axis direction side), and the configuration of the lid 4 is simplified.

### Points of Concern

The various technological features disclosed in the present specification are able to be modified in various ways without departing from the spirit of the technological creation. That is, the foregoing embodiments are examples in every aspect, and do not intend to limit the invention. The scope of the invention will be defined by the scope of claims, not by the description in the foregoing embodiments. The scope of the invention should include the scope of claims, equivalents thereof and all changes within the scope. Features of the above-described preferred embodiments may be combined appropriately as long as no conflict arises.

While the invention has been shown and described in detail, the foregoing description is in all aspects illustrative and not restrictive. It is therefore understood that numerous other modifications and variations can be devised without departing from the scope of the invention.

What is claimed is:

1. A housing of the electrical apparatus, for storing a circuit board, the circuit board having a front portion, a rear portion and a pair of first steps at a boundary therebetween such that the rear portion has a width wider than a width of the front portion, the housing comprising:
an opening through which the circuit board is inserted;
a closing wall facing to the front portion of the circuit board;
a pair of side walls extending from the opening to the closing wall and facing each other, provided with a pair of second steps adapted to the pair of first steps;
substrate guide surfaces, each provided on corresponding one of the side walls;
a pair of first holders extending from the closing wall and provided along corresponding one of the side walls to hold a tip end of the front portion of the circuit board; and
a pair of second holders extending from the pair of the second steps and provided along corresponding one of the side walls to hold the rear portion of the circuit board, the pair of second holders keeping a gap between the circuit board and the substrate guide surfaces.

2. The housing of the electrical apparatus according to claim 1, wherein
the first holder holds the front portion of the circuit board while being positioned away from the substrate guide surface in a normal direction of the substrate guide surface.

3. The housing of the electrical apparatus according to claim 2, wherein
the first holder and the second holder are positioned away from the substrate guide surface in the normal direction of the substrate guide surface by a same distance.

4. The housing of the electrical apparatus according to claim 1, wherein
insertion openings of the first holder and the second holder for the circuit board face in a direction in which the opening is located.

5. The housing of the electrical apparatus according to claim 4, wherein
each of the first holder and the second holder has a slope that is inclined toward each insertion opening to be away from the substrate guide surface as approaching from the opening to each insertion openings.

6. The housing of the electrical apparatus according to claim 1, wherein
a plurality of sets of the substrate guide surfaces, the first holders, and the second holders are arranged in parallel in normal directions of the substrate guide surfaces.

7. An electrical apparatus comprising:
the housing of the electrical apparatus according to claim 1; and
a lid covering the opening of the housing.

8. The electrical apparatus according to claim 7, wherein
the lid has a third holder holding the circuit board.

9. The electrical apparatus according to claim 8, wherein
the third holder holds the circuit board while being positioned away from the substrate guide surface in a normal direction of the substrate guide surface.

10. The electrical apparatus according to claim 9, wherein
the first holder, the second holder, and the third holder are positioned away from the substrate guide surface in the normal direction of the substrate guide surface by a same distance.

11. The electrical apparatus according to claim 8, wherein
the housing of the electrical apparatus has two sets of the substrate guide surfaces, the first holders, and the second holders that are arranged in parallel in normal directions of the substrate guide surfaces, and
the lid has the third holder that faces one of the two sets of the substrate guide surfaces, the first holders, and the second holders in an insertion direction of the circuit board by switching orientation of the lid in the normal directions of the substrate guide surfaces.

12. A circuit board housing case for storing a circuit board, the circuit board having a rectangular whose width on a side of a rear end is wider than a width on a side of a tip end, comprising:
an opening to insert the circuit board from the tip end of the circuit board;
a first side wall coming into contact with the tip end of the circuit board;
a pair of second side walls extending from the first side wall to the opening and facing each other, provided with steps configured such that a width between the pair of second side walls is wider on a side of the opening than a side of the first side wall;
a substrate guide surface provided on the pair of second side walls;
a first holder provided on the first side wall and extending to the side of the opening; and
a second holder provided on the steps and extending to the side of the opening, wherein
the first holder and the second holder hold the circuit board while being positioned away from the substrate guide surface in a normal direction of the substrate guide surface.
